(19) United States
(12) Patent Application Publication
(10) Pub. No.: US 2007/0167013 A1
(43) Pub. Date: Jul. 19, 2007

(54) Method for performing a CMP process on a wafer formed with a conductive layer

(75) Inventor: Young Seok Jeong, Yeopje-gu (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd.

(21) Appl. No.: 11/644,889

(22) Filed: Dec. 26, 2006

(30) Foreign Application Priority Data
Dec. 29, 2005 (KR) 10-2005-0133179

(51) Int. Cl. H01L 21/302

(52) U.S. Cl. 438/691

(57) ABSTRACT

A CMP method for performing a chemical mechanical polishing process wherein an edge of a wafer formed with a conductive layer is uniformly polished is provided. The CMP method includes preparing a wafer, forming a chip pattern in effective dies of the wafer and ineffective dies on edges of the wafer, depositing an insulating layer on the wafer, forming a trench and via hole in a portion of the insulating layer deposited on the effective die, forming a conductive layer on the wafer, and performing a CMP process on the wafer until a portion of the conductive layer formed on the ineffective die is removed.

### RELATED APPLICATION

This application is based upon and claims the benefit of priority to Korean Application No. 10-2005-0133179, filed on Dec. 29, 2005, the entire contents of which are incorporated herein by reference.

### BACKGROUND

1. Technical Field

The present invention relates to a CMP (Chemical Mechanical Polishing) method, and more particularly to a CMP method wherein an edge of a wafer formed with a conductive layer can be uniformly polished.

2. Description of the Related Art

As semiconductor devices become more highly integrated, a technology for planarizing a lower semiconductor structure in order to secure a margin in a photo process and to minimize the length of an interconnection is required.

Conventional methods for planarizing a lower semiconductor structure includes BPSG (borophosphosilicate glass) reflow, aluminum reflow, spin on glass (SOG), etch-back, CMP (Chemical Mechanical Polishing) processes and the like.

Among these processes, the CMP process is a process capable of effectively planarizing wafers, in which slurry is inserted between a wafer and a polishing pad such that the wafer is polished. Since the method can accomplish global planarization in a broad space and at low-temperatures, which cannot be accomplished through a reflow or etch-back process, the method has been spotlighted as a leading planarization technology for next-generation devices.

The CMP process is used in a case where, after etching a trench, an insulating layer is filled in the trench and planarization is then accomplished in a trench device isolation method rather than a device isolation method through existing thermal oxidation; in a damascene process in which, when forming lines and spaces, a reverse pattern is formed, a conductive material is filled in the lines and spaces, and planarization and line isolation are then accomplished; or in a process of planarizing an interlayer dielectric layer. Accordingly, the CMP process can accomplish planarization while reducing thermal budget.

In order to use an insulating layer as a polishing stop layer, a polishing compound used in a CMP process for a metal layer is generally prepared to have a high polishing speed for a metallic material and to have a low polishing speed for an insulating layer.

FIG. 1 is a view showing a conventional wafer.

As shown in FIG. 1, the conventional wafer has a plurality of pattern areas 11a in each of which a pattern is formed and a plurality of non-pattern area 11b in each of which a pattern is not formed.

Here, each of pattern areas 11a corresponds to an area adjacent to non-pattern area 11b among effective dies, and each of non-pattern areas 11b corresponds to an ineffective die corresponding to an edge of a wafer. The effective die is a die on which a desired chip pattern is formed by a user, and the ineffective die is a die on which a chip pattern is not formed.

Meanwhile, a plurality of metal patterns and an insulating layer for insulating between metal patterns are formed in each of the pattern areas 11a, and insulating layer is formed in each of non-pattern areas 11b.

At this time, the metal patterns are not formed in each of non-pattern areas 11b because non-pattern areas 11b are ineffective dies. Since an insulating layer which is not required for a photolithography process is formed on the entire surface of the wafer, the insulating layer is also formed in non-pattern areas 11b except the pattern areas 11a.

However, since devices are not formed on non-pattern areas 11b, the aforementioned metal patterns are not formed in each of non-pattern areas 11b.

Accordingly, since the thickness of an insulating layer formed in pattern areas 11a is different from that of the insulating layer formed in non-pattern areas 11b, a step difference occurs.

Copper is typically used as a material of the metal pattern due to demands for a faster response speed of devices and is typically formed using a dual damascene technique. Accordingly, interconnections are formed after the CMP process. At this time, since copper is not removed sufficiently in the CMP process due to the aforementioned step difference between pattern and non-pattern areas 11a and 11b, the copper remains on the insulating layer, resulting in an electric leakage of the interconnections.

This will be described below in more detailed manner.

FIGS. 2a and 2b are sectional views taken along line I-I in FIG. 1.

First, a wafer 11 having pattern and non-pattern areas 11a and 11b are prepared, and a transistor is formed in each of pattern areas 11a of wafer 11. Further, an insulating layer 51 is formed on the entire surface of wafer 11.

Then, a trench and a via hole, which have a dual damascene structure, are formed in the insulating layer 51, and an anti-diffusion layer 52, a copper seed layer 53 and a copper metal layer 54 are sequentially formed on the entire surface of wafer 11 including the trench and via hole.

At this time, since a transistor is formed in pattern area 11a and a transistor is not formed in the non-pattern area 11b, insulating layer 51 formed on the entire surface of wafer 11 has a different thickness in each of the areas.

That is, the thickness of insulating layer 51 in the pattern area 11a is thicker than that of insulating layer 51 in non-pattern area 11b.

Then, if copper metal layer 54 is polished using a CMP process, a copper interconnection layer 55 is formed in the trench and via hole as shown in FIG. 2b. At this time, a copper metal layer 56 is not completely removed and remains in non-pattern area 11b due to the step difference of insulating layer 51.

The remaining copper metal layer 56 (a copper residue) may penetrate through a rear surface of the pattern area 11a or wafer 11 in following processes such that copper metal layer 56 causes an electric leakage of interconnections.

### BRIEF SUMMARY

The present invention addresses the above problem occurring in the prior art, and provides a CMP method wherein the same pattern is formed in pattern and non-pattern areas, thereby minimizing a step difference of an insulating layer, so that copper residues can be removed.

Consistent with the present invention, there is provided a method for performing a CMP (Chemical Mechanical Polishing) process, comprising: preparing a wafer; dividing the wafer into pattern areas serving as effective dies and non-pattern areas serving as ineffective dies; forming a transistor in the pattern and non-pattern areas; forming an insulating layer on the wafer; forming a trench and a via hole at a portion of the insulating layer positioned in the pattern areas; forming an anti-diffusion layer on the wafer; forming a conductive layer on the semiconductor wafer; and planarizing the conductive layer by using a CMP process.

The non-pattern area may be an edge area of the semiconductor wafer, and the pattern area may be an effective die adjacent to the non-pattern area.

The CMP process is performed until the conductive layer on the non-pattern area is removed.

Further consistent with the present invention, there is provided a method for performing a CMP method on a wafer, which includes: preparing a wafer; forming a chip pattern in effective dies of the wafer and ineffective dies on edges of the wafer; depositing an insulating layer on the wafer; forming a trench and via hole in a portion of the insulating layer deposited on the effective die; forming a conductive layer on the wafer; and performing a CMP process on the wafer until a portion of the conductive layer formed on the ineffective die is removed.

### BRIEF DESCRIPTION OF DRAWINGS

FIG. 1 is a view showing a conventional wafer;

FIGS. 2a and 2b are sectional views taken along line I-I in FIG. 1;

FIG. 3 is a view showing a wafer consistent with the present invention;

FIGS. 4a to 4g are sectional views illustrating a CMP method consistent with the present invention; and

FIGS. 5a and 5b are sectional views illustrating a method of forming a copper interconnection on the wafer shown in FIG. 4g.

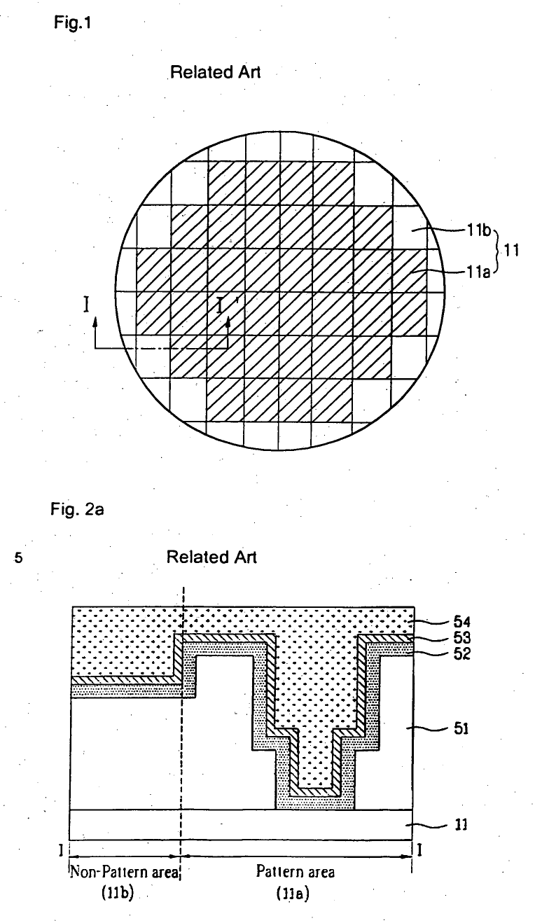

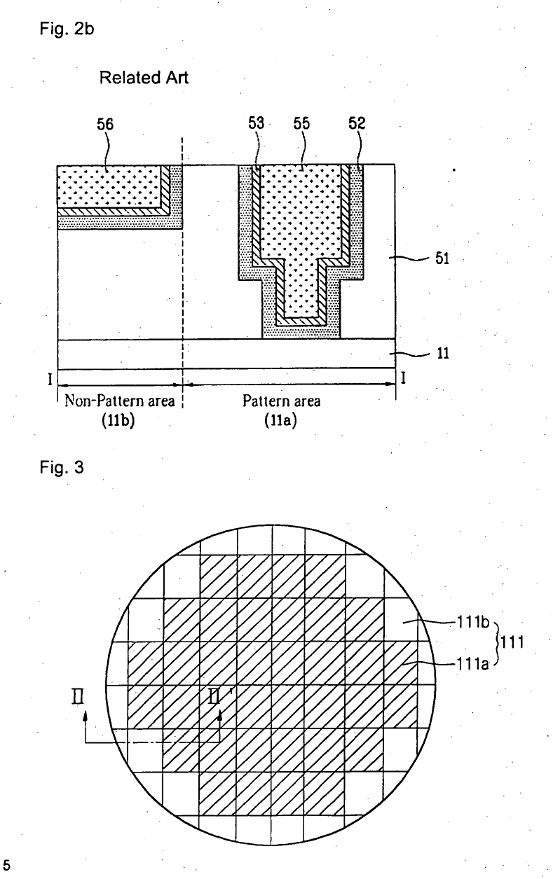

### DETAILED DESCRIPTION

Hereinafter, a CMP method according to a preferred embodiment of the present invention will be described with reference to the accompanying drawings.

FIG. 3 is a view showing a wafer consistent with the present invention. As shown in this figure, the same pattern is formed in both pattern and non-pattern areas 110a and 110b of a wafer 110. Here, each of pattern areas 110a corresponds to an area adjacent to non-pattern area 110b among effective dies, and each of non-pattern areas 110b corresponds to an ineffective die corresponding to an edge of wafer 110. The effective die is a die on which a desired chip pattern is formed by a user, and the ineffective die is a die on which a chip pattern is not formed. Here, the chip pattern may be a transistor that is a semiconductor device, or the like.

At this time, it is possible to form the pattern in non-pattern area 110b adjacent to pattern area 110a or to form the pattern in all the respective non-pattern areas 110b. Here, the pattern may be a transistor. This will be described below in detail.

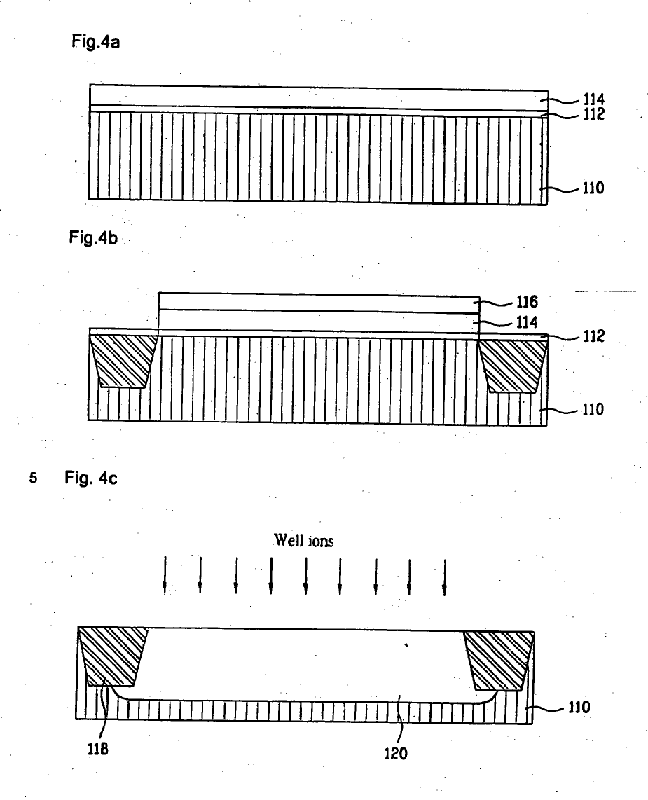

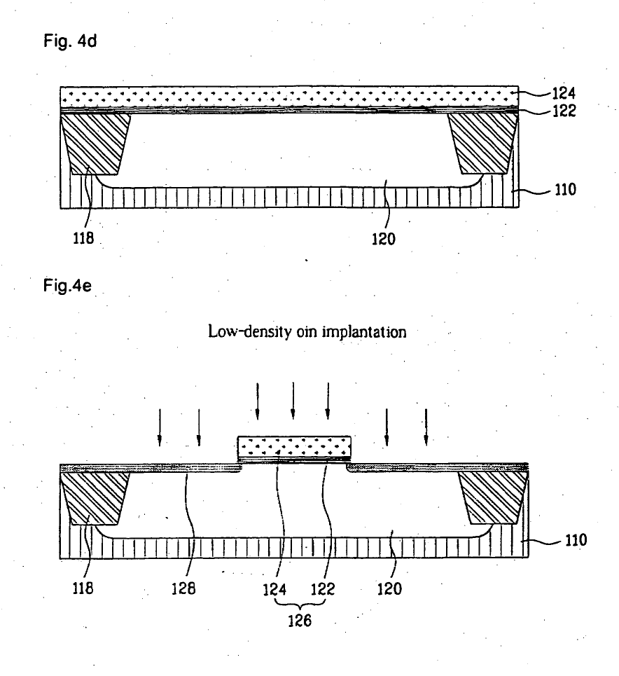

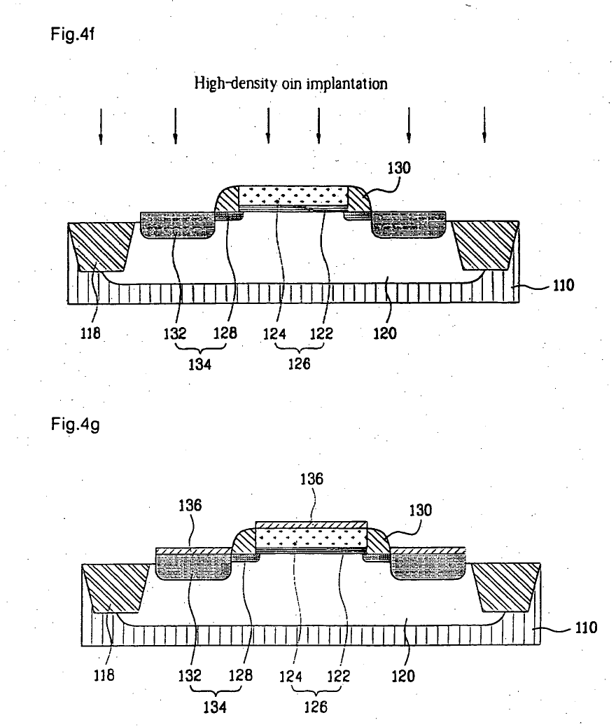

FIGS. 4a to 4g are sectional views illustrating a CMP method consistent with the present invention.

Referring to FIG. 4a, a pad oxide layer 112 and a pad nitride layer 114 are sequentially formed on the entire surface of a semiconductor wafer 110 for forming an isolation region in the following process.

Referring to FIG. 4b, a photoresist is deposited on the entire surface of the semiconductor wafer 110 having pad oxide layer 112 and pad nitride layer 114, and an exposure process using a photomask is then performed, thereby forming a photoresist pattern 116. Subsequently, an STI (Shallow Trench Isolation) process is performed by using photoresist pattern 116 as an ISO mask, thereby forming isolation layers 118. At this time, semiconductor wafer 110 is divided into an active area and a non-active area (i.e., an isolation layer area) by isolation layer 118.

Referring to FIG. 4c, after removing photoresist pattern 116 by performing a stripping process, a predetermined washing process is performed, thereby sequentially removing pad nitride layer 114 and pad oxide layer 112. Subsequently, a well ion implantation process is performed by using a mask for well ion implantation, thereby forming a well area 120 in semiconductor wafer 110.

Referring to FIG. 4d, a thermal oxidation or rapid heat treatment process is performed on the entire surface of semiconductor wafer 110, thereby forming a gate oxide layer 122.

Subsequently, a poly-silicon layer 124 for gate electrodes is formed on the entire surface of semiconductor wafer 110 formed with the gate oxide layer 122.

Referring to FIG. 4e, a photolithography process is performed by using a mask for a gate electrode pattern such that poly-silicon layer 124 and gate oxide layer 122 are sequentially etched, thereby forming a gate electrode 126. Subsequently, a low-density ion implantation process for forming a shallow junction area is performed in the active area of semiconductor wafer 110, thereby forming a low-density junction area (P− or N−) 128.

Referring to FIG. 4f, predetermined deposition and etching processes are sequentially performed, thereby forming spacers 130 for LDD (Lightly Doped Drain) HLD (High temperature Low pressure Dielectric) on both sidewalls of gate electrode 126. Subsequently, a high-density ion implantation process is performed, thereby forming a high-density junction area (P+ or N+) 132. Accordingly, gate electrode 126 is doped with predetermined ions through a low-density ion implantation process. Further, source/drain areas 134 each having low-density and high-density junction areas 128 and 132 are formed.

Meanwhile, if an edge of isolation layer 118 is etched in a process of forming spacer 130, the thickness of isolation layer 118 at an edge portion is reduced. Therefore, there occurs a step difference between isolation layer 118 and source/drain area 134. At this time, source/drain area 134 is exposed at a boundary between source/drain area 134 and isolation layer 118 due to step difference.

Referring to FIG. 4g, a salicide (self align silicide) 136 is formed on high-density junction area 132 and gate electrode 126.

As such, a transistor is formed in each of pattern and non-pattern areas 110a and 110b.

Next, a method of forming copper interconnections on semiconductor wafer 110 formed with such transistors will be described below.

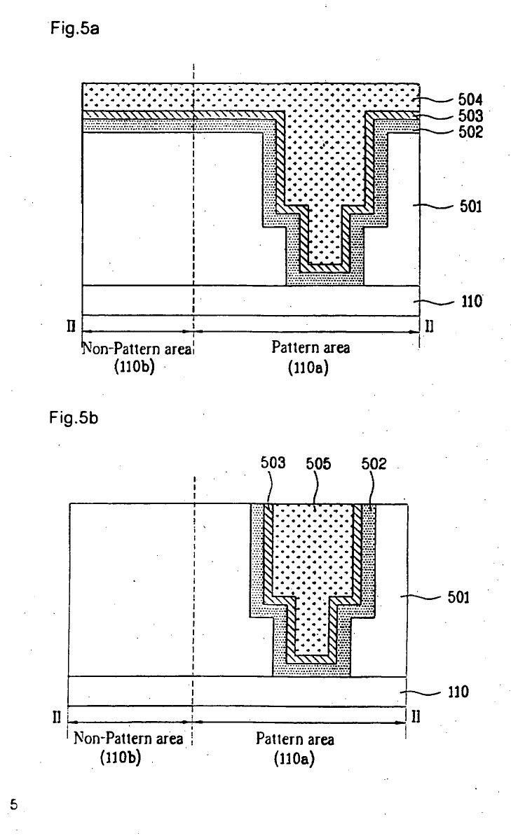

FIGS. 5a and 5b are sectional views illustrating a method of forming a copper interconnection on wafer 110 shown in FIG. 4g, and FIGS. 5a and 5b illustrate sectional views taken along line II-II in FIG. 3.

First, as shown in FIG. 5a, an insulating layer 501 is formed on the entire surface of semiconductor wafer 110.

At this time, since transistors have been formed in both pattern and non-pattern areas 110a and 110b as described above, the thickness of insulating layer 501 in pattern area 110a is identical to that of insulating layer 501 in non-pattern area 110b.

Then, insulating layer 501 of pattern area 110a is patterned, thereby forming a trench and a via hole. Subsequently, an anti-diffusion layer 502 and a conductive layer are formed on the entire surface of semiconductor wafer 110 including the trench and the via hole. Here, the conductive layer includes a copper seed layer 503 and a copper metal layer 504.

Then, if anti-diffusion layer 502, copper seed layer 503 and copper metal layer 504 are polished through a CMP process until a surface of the insulating layer 501 is exposed, a copper interconnection layer 505 is formed in the trench and the via hole as shown in FIG. 5b.

At this time, since insulating layers 501 of both pattern and non-pattern areas 110a and 110b have the same thickness, copper metal layer 504 on insulating layer 501 is completely removed.

That is, according to the CMP method of the present invention, copper residues are not produced.

Meanwhile, the trench and the via hole and the copper interconnection layer, which are formed in pattern area 110a, may also be formed in non-pattern area 110b.

As described above, the same pattern is formed in pattern and non-pattern areas so that there can be reduced a step difference between insulating layers formed in the pattern and non-pattern areas.

That is, consistent with the present invention, a predetermined dummy pattern is formed even in a non-pattern area that is an edge of a wafer, and an exposure process is then performed.

Accordingly, an insulating layer deposited on the entire surface of the wafer after forming the dummy pattern can be uniformly deposited on the wafer. Thus, it is less likely that there occur a step difference between a non-pattern area and a pattern area adjacent thereto.

Therefore, copper residues can be prevented from being produced in a CMP process.

The present invention may remove a step difference between a non-pattern area corresponding to an edge of a wafer and a pattern area adjacent thereto. Accordingly, a conductive layer can be prevented from remaining in a non-pattern area in a case where a CMP process is performed.

It will be apparent to those skilled in the art that various modifications and variations can be made in the present invention. Thus, it is intended that the present invention covers the modifications and variations thereof within the scope of the appended claims.

What is claimed is:

1. A method for performing a CMP (Chemical Mechanical Polishing) process on a wafer formed with a conductive layer, comprising:
preparing a wafer;
dividing the wafer into pattern areas serving as effective dies and non-pattern areas serving as ineffective dies;
forming a transistor in the pattern and non-pattern areas;
forming an insulating layer on the wafer;
forming a trench and a via hole at a portion of the insulating layer positioned in the pattern areas;
forming an anti-diffusion layer on the wafer including the trenches and the via holes;
forming a conductive layer on the wafer; and
planarizing the conductive layer by performing a CMP process.

2. The CMP method of claim 1, wherein dividing the wafer comprises:
dividing an edge area of the wafer into the non-pattern area, and dividing an effective die adjacent to the non-pattern area into the pattern area.

3. The CMP method of claim 1, wherein planarizing the conductive layer comprises:
performing the CMP process such that the conductive layer on the non-pattern area is removed.

4. A method for performing a CMP process on a wafer formed with a conductive layer, comprising:
preparing a wafer;
forming a chip pattern in effective dies of the wafer and ineffective dies on edges of the wafer;
depositing an insulating layer on the wafer;
forming a trench and via hole in a portion of the insulating layer deposited on the effective die;
forming a conductive layer on the wafer; and
performing a CMP process on the wafer until at least a portion of the conductive layer formed on the ineffective die is removed.
